(19) United States
(12) Patent Application Publication
(10) Pub. No.: US 2017/0133633 A1
(43) Pub. Date: May 11, 2017

(54) OLED, METHOD FOR MANUFACTURING THE SAME, DISPLAY SUBSTRATE AND DISPLAY DEVICE

(71) Applicant: BOE TECHNOLOGY GROUP CO., LTD., Beijing (CN)

(72) Inventors: Xinxin WANG, Beijing (CN); Rui PENG, Beijing (CN); Kai XU, Beijing (CN); Ronggang SHANGGUAN, Beijing (CN)

(21) Appl. No.: 15/295,138

(22) Filed: Oct. 17, 2016

(30) Foreign Application Priority Data
Nov. 5, 2015 (CN) 201510745035.2

(51) Int. Cl. H01L 51/52; H01L 51/56; H01L 51/50

(52) U.S. Cl. CPC H01L 51/5268; H01L 51/506; H01L 51/5076; H01L 51/5088; H01L 51/5092; H01L 51/56

(57) ABSTRACT

An organic light emitting diode (OLED), a method for manufacturing the same, a display substrate and a display device are disclosed. The organic light-emitting diode (OLED) includes an electron transporting layer and a hole transporting layer; at least one of the electron transporting layer and the hole transporting layer is doped with nanoparticles or nanowires made of a semiconductor material.

### TECHNICAL FIELD

Embodiments of the disclosure relate to the field of display technologies, more particularly, to an organic light-emitting diode (OLED), a method for manufacturing the same, a display substrate, and a display device.

### BACKGROUND

Organic Light Emitting Diode (OLED) technologies attract most attention among currently available flat panel display technologies. An OLED comprises an anode layer, a hole injection layer, a hole transporting layer, a light emitting layer, an electron transporting layer, an electron injection layer, and a cathode layer. In order to increase the conductivity of an OLED device, the hole transporting layer and/or the electron transporting layer will generally be doped. However, the light emitting efficiency of the doped OLED device in conventional technologies is not increased much.

### SUMMARY

Embodiments of the present disclosure provides an OLED, a method for manufacturing the same, a display substrate and a display device so as to increase the light emitting efficiency of the OLED while increasing the efficiency of the OLED and reducing the voltage.

In a first aspect, an embodiment of the disclosure provides an organic light-emitting diode (OLED), comprising an electron transporting layer and a hole transporting layer, wherein at least one of the electron transporting layer and the hole transporting layer is doped with nanoparticles or nanowires made of a semiconductor material.

In a second aspect, an embodiment of the present disclosure provides a method for manufacturing an organic light emitting diode (OLED), comprising: providing a solution; doping the solution with nanowires or nanoparticles made of a semiconductor material, wherein a material of forming the nanowires and the nanoparticles is an N-type semiconductor material or a P-type semiconductor material; and coating the solution doped with the nanowires or nanoparticles on a base substrate.

In a third aspect, an embodiment of the present disclosure provides a display substrate comprising the above OLED.

In a fourth aspect, an embodiment of the present disclosure provides a display device comprising the above display substrate.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 schematically illustrates a diagram of an OLED in accordance with an embodiment of the disclosure;

FIG. 2 schematically illustrates another diagram of an OLED in accordance with an embodiment of the disclosure;

FIG. 3 schematically illustrates a flow chart of a method for manufacturing an OLED in accordance with an embodiment of the disclosure;

FIG. 4 schematically illustrates a cross section of a substrate and a metal oxide layer having nanopores in accordance with an embodiment of the disclosure;

FIG. 5 schematically illustrate a top view of the nanopores;

FIG. 6 schematically illustrates a substrate having nanowires formed therein in accordance with an embodiment of the disclosure; and

FIG. 7 schematically illustrates nanowires mixed in a solution for forming a film layer in accordance with an embodiment of the disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

The inventors have noted that a hole transporting layer may be doped with a P-type dopant to and/or an electron transporting layer may be doped with an N-type dopant; the P-type dopant is mostly Molybdenum Oxide, Tungsten Oxide, Cesium Carbonate, and the N-type dopant is mostly alkali metal compound such as Lithium Fluoride. During the manufacturing process, the P-type doped hole transporting layer is formed by evaporating a material(s) having a P-type dopant; or else, the N-doped electron transporting layer is formed by evaporating a material(s) having an N-type dopant. A structure formed through evaporation processes can improve the efficiency of an OLED device itself and reduce the voltage.

An embodiment of the disclosure provides an OLED, which comprises an electron transporting layer and a hole transporting layer; at least one of the electron transporting layer and the hole transporting layer is doped with nanoparticles or nanowires made of a semiconductor material(s).

As N-type dopants and P-type dopants in the embodiment of the disclosure arc nanowires or nanoparticles at the order of nanometers, diameters of the nanowires and nanoparticles are at the order of nanometers. If the nanowires or nanoparticles are distributed in the films/layers of the OLED in large quantity, they can increase the scattering of light, thus increasing the light emitting efficiency of the OLED as well as an external quantum efficiency thereof, thereby improving a display effect of a display device.

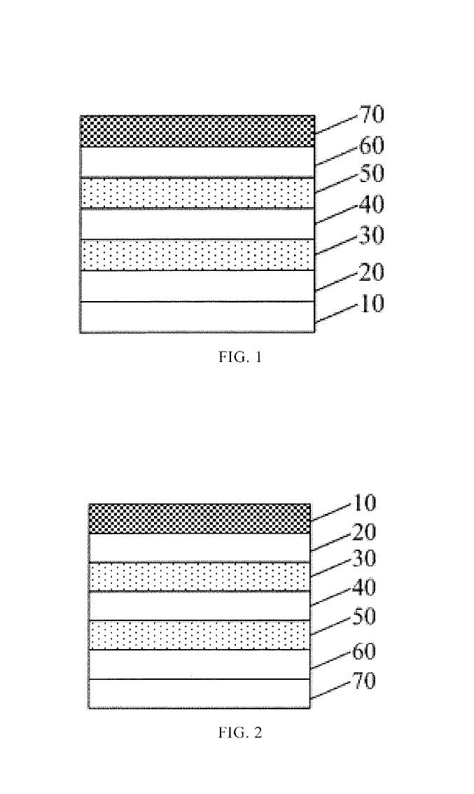

Another embodiment of the disclosure provides an OLED. As illustrated in FIG. 1 and FIG. 2, the OLED comprises a hole transporting layer 30 and an electron transporting layer 50, the electron transporting layer 50 is doped with an N-type dopant, the N-type dopant comprises a plurality of nanoparticles or nanowires made of an N-type semiconductor material; and/or the hole transporting layer 30 is doped with a P-type dopant, the P-type dopant comprises a plurality of nanoparticles or nanowires made of a P-type semiconductor material.

As the P-type dopant has a lower Fermi level and is closer to the highest occupied molecular orbital (HOMO) of the hole transporting layer 30, and the N-type dopant has a higher Fermi level and is closer to the lowest unoccupied molecular orbital (LUMO) of the electron transporting layer 50, the mobility of the electrons and holes is thus increased and the conductivity is improved. The energy released by the recombination of the electrons and holes is transmitted to molecules of a light emitting layer 40 and excites the molecules of the light emitting layer 40 to further produce the phenomenon of light emitting. As the N-type dopant and the P-type dopant in the embodiment of the disclosure are nanowires or nanoparticles at the order of nanometers, diameters of the nanowires and nanoparticles are at the order of nanometers. When such nanowires or nanoparticles are distributed in films/layers of the OLED device in large quantity, they can increase the scattering of light, thus increasing the light emitting efficiency of the OLED as well as an external quantum efficiency thereof.

In at least some embodiments, diameters of the nanowires are in the range from 5 nm to 100 nm, lengths of the nanowires are in the range from 0.2 μm to 20 μm, and particle sizes of the nanoparticles are in the range from 5 nm and 100 nm.

In at least some embodiments, the N-type semiconductor materials may comprise any one of Zinc Selenide (ZnSe) or Zinc Fluoride (ZnF2); the P-type semiconductor materials may comprise any one of Bismuth Telluride (Bi2Te3), Cadmium Sulfide (CdS), Cadmium Selenide (CdSe), Gallium Nitride (GaN), Titanium Dioxide (TiO2), or Zinc Oxide (ZnO).

In at least some embodiments, the OLED further comprises an anode layer 10, a cathode layer 70, a hole injection layer 20, a light emitting layer 40, and an electron injection layer 60; the hole injection layer 20, the hole transporting layer 30, the light emitting layer 40, the electron transporting layer 50 and the electron injection layer 60 are between the anode layer 10 and the cathode layer 70 and disposed successively along the direction from the anode layer 10 to the cathode layer 70. The specific form of the OLED is not defined in the disclosure, as long as the hole transporting layer 30 is doped with the nanowires and nanoparticles made of a P-type semiconductor material and/or the electron transporting layer 50 is doped with nanowires and nanoparticles made of an N-type semiconductor material.

As an example illustrated in FIG. 1, the OLED may be a bottom-emitting non-inverted OLED, the anode layer 10 of which is made of a transparent material, and the cathode layer 70 of which is made of a light tight metal material. Alternatively, as illustrated in FIG. 2, the OLED is a bottom-emitting inverted OLED, the anode layer 10 of the OLED is made of a light tight metal material, and the cathode layer 70 of the OLED is made of a transparent material.

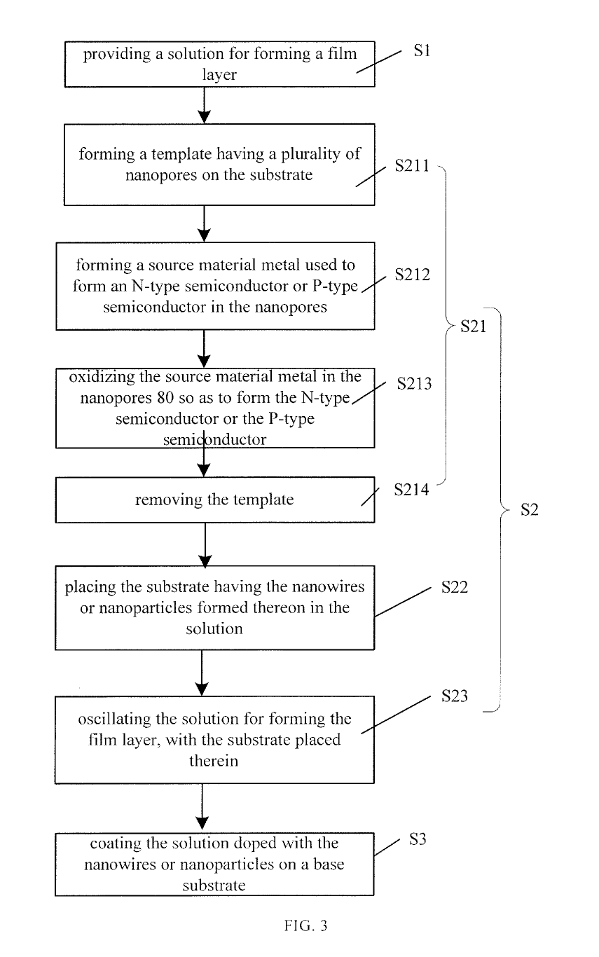

Another embodiment of the disclosure provides a method for manufacturing an OLED. As illustrated in FIG. 3, the method comprises the following operations:

S1, providing a solution for forming a film layer;

S2, doping the solution for forming the film layer with nanowires or nanoparticles made of a semiconductor material;

S3, coating the solution doped with the nanowires or nanoparticles on a base substrate so as to form the film layer that is needed.

In at least some embodiments, when the film layer to be formed is the electron transporting layer 50, the solution for forming a film layer may he for example an aqueous solution of fullerene derivatives (PCBM), and the material for forming the nanowires 31 and the nanoparticles is an N-type semiconductor material(s), that is, it may dope the solution for forming the electron transporting layer 50 with nanowires or nanoparticles made of an N-type semiconductor. When the film layer to be formed is the hole transporting layer 30, the solution for forming the film layer may be an aqueous solution of polymer (PEDOT: PSS) including 3,4-ethylenedioxythiophene monomers and polystyrene sulfonate, and the material for forming the nanowires and the nanoparticles is a P-type semiconductor material, that is, it may dope the solution to form the hole transporting layer 30 with nanowires or nanoparticles made of a P-type semiconductor.

In an OLED manufactured by the above method, the electron transporting layer 50 contains nanowires or nanoparticles made of an N-type semiconductor material, and the hole transporting layer is doped with nanowires or nanoparticles made of a P-type semiconductor. By this means, the N-type doping process or the P-type doping process can increase an electrical conduction efficiency of the OLED, moreover, the nanowires and nanoparticles can also increase the scattering effect of lights, thereby increasing the light emitting efficiency of the components.

In at least some embodiments, as illustrated in FIG. 3, the operation S2 may further comprise:

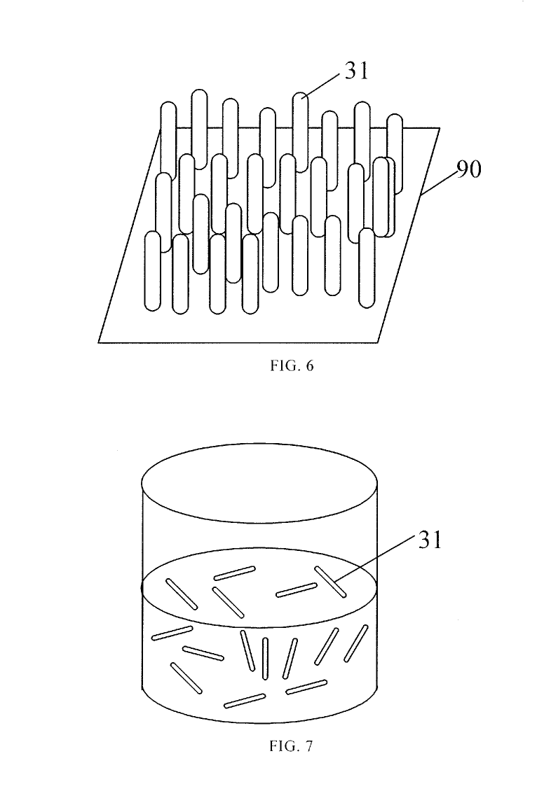

S21, forming a plurality of nanowires 31 or nanoparticles on a substrate 90 (as illustrated in FIG. 6);

S22, placing the substrate 90 having the nanowires 31 or nanoparticles formed thereon in the solution for forming the film layer;

S23, oscillating the solution for forming the film layer, with the substrate placed therein, such that the nanowires 31 or nanoparticles are detached from the substrate 90, thereby obtaining a solution doped with the nanowires 31 or nanoparticles (as illustrated in FIG. 7).

In at least some embodiments, the operation S23 may further comprise: performing ultrasonic oscillation in the solution by means of an ultrasonic oscillation apparatus. The oscillation power and oscillation time period can be determined as needed, until the nanowires 31 and nanoparticles are detached from the substrate 90.

In the embodiment of the disclosure, the plurality of nanowires 31 and nanoparticles are formed through a template process for example. In at least some embodiments, as illustrated in FIG. 3, the operation S21 may further comprise the following operations:

S211, forming a template having a plurality of nanopores 80 on the substrate 90, wherein apertures of the nanopores 80 are at the order of nanometers;

S212, forming a source material metal used to form an N-type semiconductor or P-type semiconductor in the nanopores 80;

S213, oxidizing the source material metal in the nanopores 80 so as to form the N-type semiconductor or the P-type semiconductor; and

S214, removing the template.

In at least some embodiments, the source material metal used to form an N-type semiconductor or P-type semiconductor may be formed in the nanopores 80 through an electrodeposion process. The source material metal reacts with a reaction gas or liquid to form the N-type semiconductor or P-type semiconductor. The source material metal may be a metal capable of forming a semiconductor. As an example, when the electron transporting layer 50 is to be formed, the material for forming the nanowires 31 or nanoparticles is an N-type semiconductor material such as Zinc Selenide (ZnSe), correspondingly, the source material metal is Zinc; when the hole transporting layer 30 is to be formed, the material for forming the nanowires 31 or nanoparticles is a P-type semiconductor material such as Cadmium Selenium (CdSe), or Gallium Nitride (GaN), correspondingly, the source material metal is Cadmium or Gallium. It is noted that, when oxidizing the source material metal during the step S213, the term “oxidizing” as used herein is in general sense, i.e., a process that the source material metal lose electrons, and is not limited to the situation where the source material metal reacts with a gas or solution containing oxygen.

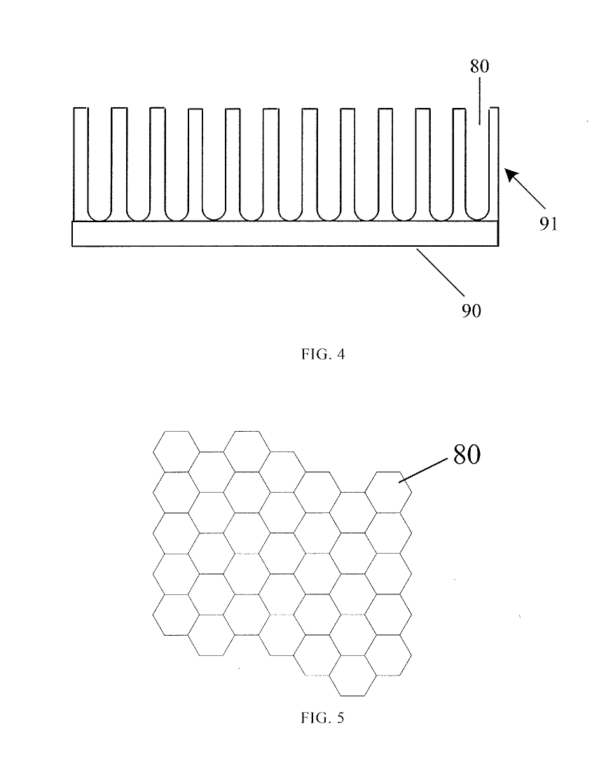

Various templates can be used to manufacture the nanowires 31. As a specific embodiment of the disclosure, the substrate 90 is a metal substrate, and the step S211 for example can be conducted as follows: placing the substrate 90 in an electrolyte solution to have the substrate 90 anodized, thereby forming a metal oxide layer 91 on a surface of the substrate 90; eroding the metal oxide layer 91 by the electrolyte solution to form the plurality of nanopores 80. As illustrated in FIG. 4 and FIG. 5, the metal oxide layer 91 having the nanopores formed thereon is the template. During the anodization process, the metal substrate functions as an anode. During the electrolyzation process, anions of oxygen react with the metal substrate to form the metal oxide layer 91. With the increase in the thickness of the film, the resistance of the metal oxide layer 91 also becomes larger, causing an electrolysis current to be smaller. At this time, the metal oxide layer 91 in contact with the electrolyte solution partly dissolves to form the plurality of nanopores 80 at the order of nanometers. The apertures and lengths of the nanopores 80 can be adjusted by adjusting the type of the electrolyte solution, the electrolysis temperature, the electrolysis time period, etc.

The metal used to manufacture the substrate 90 may be an active metal. In the embodiment of the disclosure, the substrate 90 is for example an aluminum sheet, the electrolyte is a mixture of one or more of such as sulfuric acid, oxalic acid, or phosphoric acid, the aluminum sheet is anodized in the acid electrolyte to form an alumina film layer, a plurality of nanopores 80 at the order of nanometers is formed in the alumina, and the alumina having the nanopores 80 formed thereon will be used as the template for forming the nanowires or nanoparticles.

In at least some embodiments, before the step of placing the substrate 90 in an electrolyte solution, the manufacturing method may further comprise the following operation: annealing or polishing the substrate so as to increase the degree of homogeneous distribution of the metal particles on the surface of the substrate 90. As an example, during the annealing process, the anneal may last for two to four hours in a nitrogen condition, and the anneal temperature may be 450° to 550°. The polishing may be realized for example by a chemical polishing process or an electrochemical polishing process.

In at least some embodiments, the step of removing the template may comprise the following operations: dissolving the metal oxide layer by using an alkaline solution, and retaining the N-type semiconductor or the P-type semiconductor in the nanopores 80, wherein the alkaline solution may be sodium hydroxide.

As an example, during the process of dissolving the metal oxide layer by using an alkaline solution, it may perform an ultrasonic oscillation with respect to the alkaline solution by means of an ultrasonic oscillation apparatus, thereby accelerating the dissolution speed.

In another detailed embodiment of the disclosure, a carbon nanotube array is used as the template, and the carbon nanotubes are formed through a chemical vaporous deposition (CVD) process. In at least some embodiments, the substrate 90 is a quartz substrate, and the step of forming a template having a plurality of nanopores 80 on the substrate 90 comprises the following operations: placing the substrate 90 in a reaction chamber; introducing a reaction gas to the reaction chamber so as to form a carbon nanotube array, the carbon nanotube array is the template having a plurality of nanopores 80.

In at least some embodiments, the reaction gas comprises a mixture of gases such as hydrogen, acetylene and argon gases. The argon gas functions as a protection gas, the hydrogen gas functions as a reduction gas, and the acetylene gas is a source material gas. Before the reaction gas is introduced, a catalyst particle layer may be formed on the substrate 90, and the material of the catalyst particles are such as iron, cobalt and nickel. When the carbon nanotubes are formed, the temperature of the reaction chamber is between 700° to 800°.

The film layer to be formed may be the electron transporting layer 50 or the hole transporting layer 30, that is, the steps S1 to S3 may be used to manufacture the electron transporting layer 50, or used to manufacture the hole transporting layer 30. As an example, both the electron transporting layer 50 and the hole transporting layer 30 are manufactured using the method provided by the steps S1 to S3. The manufacturing method for the OLED further comprises the manufacturing of organic film layers such as the hole injection layer 20, the light emitting layer 40, the electron injection layer 60 and metal electrodes. Specifically, such layers may be formed through evaporation for example.

In the above two embodiments, depths and apertures of the nanotubes 80 on the metal oxide layer may be controlled through controlling factors such as the electrolysis time period of the metal substrate in the electrolyte solution. It may also control the lengths and apertures of the carbon nanotubes through controlling factors such as the growth time period of the carbon nanotubes on the quartz substrate, the reaction temperature, etc. In at least some embodiments, the depths of the nanopores 80 on the template is in the range from 0.2 μm to 20 μm, and the apertures of the nanopores is in the range from 5 nm to 100 nm, thereby allowing lengths of the N-type semiconductor nanowires or P-type semiconductor nanowires to be between 0.2 μm and 20 μm, and diameters of the N-type semiconductor nanowires or P-type semiconductor nanowires to be between 5 nm to 100 nm.

Another embodiment of the disclosure further provides a display substrate comprising the any of the OLED described above. As the light-emitting efficiency of the OLED in the embodiment of the disclosure is increased, the display effect of the display substrate comprising the OLED is improved correspondingly.

Still another embodiment of the disclosure provides a display device comprising the above display substrate. In the embodiments of the disclosure, the N-type dopant and P-type dopant are nanowires or nanoparticles at the order of nanometers, thus increasing the scattering of lights as well as the light-emitting efficiency of the OLED, thereby increasing an external quantum efficiency of the component, and improving a display effect of a display device. Moreover, during the manufacturing of the OLED, it mixes the N-type semiconductor nanowires or P-type semiconductor nanowires in the solution for forming a film layer, and then coat the solution mixed with nanowires to form the film layer. The above method is relatively simple and suitable for scale applications.

What is described above is related to the illustrative embodiments of the disclosure only and not limitative to the scope of the disclosure; the scopes of the disclosure are defined by the accompanying claims.

The present application claims priority from Chinese Application No. 201510745035.2, filed on Nov. 5, 2015, the disclosure of which is incorporated herein by reference in its entirety.

What is claimed is:

1. An organic light-emitting diode (OLED), comprising an electron transporting layer and a hole transporting layer, wherein at least one of the electron transporting layer and the hole transporting layer is doped with nanoparticles or nanowires made of a semiconductor material.

2. The OLED of claim 1, wherein the electron transporting layer is doped with an N-type dopant, and the N-type dopant comprises a plurality of nanoparticles or nanowires made of an N-type semiconductor material.

3. The OLED of claim 1, wherein the hole transporting layer is doped with a P-type dopant, and the P-type dopant comprises a plurality of nanoparticles or nanowires made of a P-type semiconductor material.

4. The OLED of claim 2, wherein the hole transporting layer is doped with a P-type dopant, and the P-type dopant comprises a plurality of nanoparticles or nanowires made of a P-type semiconductor material.

5. The OLED of claim 1, wherein diameters of the nanowires are in a range from 5 nm to 100 nm, lengths of the nanowires are in a range from 0.2 μm to 20 μm, and particle sizes of the nanoparticles are in a range from 5 nm to 100 nm.

6. The OLED of claim 4, wherein the N-type semiconductor materials comprise any one of Zinc Selenide or Zinc Fluoride; the P-type semiconductor materials comprise any one of Bismuth Telluride, Cadmium Sulfide, Cadmium Selenide, Gallium Nitride, Titanium Dioxide, or Zinc Oxide.

7. A method for manufacturing an organic light emitting diode (OLED), comprising:
providing a solution;
doping the solution with nanowires or nanoparticles made of a semiconductor material, wherein a material of forming the nanowires and the nanoparticles is an N-type semiconductor material or a P-type semiconductor material; and
coating the solution doped with the nanowires or nanoparticles on a base substrate.

8. The method of claim 7, wherein doping the solution with nanowires or nanoparticles made of the semiconductor material comprises:
forming a plurality of nanowires or nanoparticles on a substrate;
placing the substrate having the nanowires or nanoparticles formed thereon in the solution; and
oscillating the solution having the substrate placed therein such that the nanowires or nanoparticles are detached from the substrate.

9. The method of claim 8, wherein the step of oscillating the solution having the substrate placed therein comprises: performing ultrasonic oscillation on the solution using an ultrasonic oscillation apparatus.

10. The method of claim 8, wherein forming the plurality of nanowires or nanoparticles on the substrate comprises:
forming a template having a plurality of nanopores on the substrate, and apertures of the nanopores are at the order of nanometers;
forming a source material metal used to form the N-type semiconductor or the P-type semiconductor in the nanopores;
oxidizing the source material metal in the nanopores so as to form the N-type semiconductor or the P-type semiconductor; and
removing the template.

11. The method of claim 10, wherein the substrate is a metal substrate, and forming the template having the plurality of nanopores on the substrate comprises:
placing the substrate in an electrolyte solution to allow the substrate to be anodized, thereby forming a metal oxide layer on a surface of the substrate, eroding the metal oxide layer by the electrolyte solution to form the plurality of nanopores, wherein the metal oxide layer having the nanopores formed thereon is used as the template.

12. The method of claim 11, further comprising, before placing the substrate in the electrolyte solution and applying an anodization process to the substrate:
annealing or polishing the substrate.

13. The method of claim 11, wherein the substrate is an aluminum substrate, and removing the template comprises:
dissolving the metal oxide layer by using an alkaline solution, and retaining the N-type semiconductor or the P-type semiconductor in the nanopores.

14. The method of claim 13, wherein dissolving the metal oxide layer by using the alkaline solution comprises:
performing ultrasonic oscillation with respect to the alkaline solution by using an ultrasonic oscillation apparatus.

15. The method of claim 10, wherein the substrate is a quartz substrate, and forming a template having the plurality of nanopores on the substrate comprises:
placing the substrate in a reaction chamber; and
introducing a reaction gas to the reaction chamber so as to form a carbon nanotube array, wherein the carbon nanotube array is the template having a plurality of nanopores.

16. The method of claim 15, wherein the reaction gas is a mixture of gases comprises hydrogen, acetylene and argon gases.

17. The method of claim 10, wherein depths of the nanopores is in a range from 0.2 μm and 20 μm, and apertures of the nanopores is in a range of 5 nm to 100 nm.

18. A display substrate comprising the OLED of claim 1.

19. A display device comprising the display substrate of claim 18.
